(19) United States
(12) Patent Application Publication
(10) Pub. No.: US 2026/0150250 A1
(43) Pub. Date: May 28, 2026

(54) Prefabricated Air-Liquid Integrated Cabinet

(71) Applicant: Vertiv Tech Co., Ltd., Shenzhen (CN)

(72) Inventors: Shuai WANG, Shaanxi (CN); Xueji ZHOU, Shaanxi (CN); Junchao WANG, Shaanxi (CN); Shiying XIAO, Shaanxi (CN)

(73) Assignee: Vertiv Tech Co., Ltd., Shenzhen (CN)

(21) Appl. No.: 19/329,300

(22) Filed: Sep. 15, 2025

(30) Foreign Application Priority Data
Nov. 26, 2024 (CN) 202422895137.X

(51) Int. Cl. H05K 7/20

(52) U.S. Cl. CPC H05K 7/20781

(57) ABSTRACT

A prefabricated air-liquid integrated cabinet is disclosed to simplify wiring and pipeline connection work and reduce on-site installation and configuration work. The cabinet includes: a PDU integrated in the cabinet, an rack-based CDU, a liquid distribution unit, an air-liquid heat exchanger, a monitoring platform, and a plurality of monitoring units, wherein the PDU is connected with a power supply through a power supply interface; a primary side of the CDU is connected with a cold source through a heat exchange interface, and a secondary side of the CDU provides a cooling medium for the liquid distribution unit and the air-liquid heat exchanger; the liquid distribution unit is connected to a cold plate liquid cooling server, and supplies the cooling medium to the server; the air-liquid heat exchanger dissipates heat from the cabinet; and the monitoring platform acquires state parameters of the cabinet through the monitoring units.

### CROSS-REFERENCE TO RELATED APPLICATIONS

This application claims priority to Chinese Application No.202422895137.X, filed on Nov. 26, 2024, titled "PREFABRICATED AIR-LIQUID INTEGRATED CABINET", the entire disclosure of which is incorporated herein by reference.

### FIELD

The present disclosure relates to the technical field of cabinets, and in particular to a prefabricated air-liquid integrated cabinet.

### BACKGROUND

A density of single cabinets continues to increase with the development of data centers. As a consequence, a conventional air-cooling mode can no longer fulfill heat dissipation requirements and the energy efficiency cannot fulfill relevant requirements. Future data centers will face multiple challenges of energy consumption and heat dissipation. Therefore, liquid cooling solutions have become the development trend for future data centers, and liquid cooling with cold plates is widely used as a relatively mature liquid cooling method.

In practical applications, liquid cooling and air cooling are often used in combination with each other. However, in a case that the two are used in combination, the on-site configuration is cumbersome and multiple pipeline channels need to be configured. Meanwhile, power supply and distribution, wiring and pipeline connections work of pipeline systems are required to be completed on site.

### SUMMARY

A prefabricated air-liquid integrated cabinet is provided in the present disclosure to simplify wiring and pipeline connections work and to reduce on-site installation and configuration work.

A prefabricated air-liquid integrated cabinet is provided in the embodiments of the present disclosure, including a power distribution unit (PDU) integrated in the cabinet, a rack-based cooling distribution unit(CDU), a liquid distribution unit, an air-liquid heat exchanger, a monitoring platform and a plurality of monitoring units, wherein the PDU is connected with a power supply through a power supply interface provided by the cabinet to the outside, and is configured to supply power to at least the CDU, the air-liquid heat exchanger, a cold plate liquid cooling server installed in the cabinet, and the monitoring platform; a primary side of the CDU is connected with a cold source through a heat exchange interface provided by the cabinet to the outside, and a secondary side of the CDU is configured to provide a cooling medium to the liquid distribution unit and the air-liquid heat exchanger; the liquid distribution unit is connected to the cold plate liquid cooling server, and is configured to supply the cooling medium provided by the CDU to the cold plate liquid cooling server; the air-liquid heat exchanger is configured to dissipate heat from the cabinet; and the monitoring platform is configured to acquire state parameters of the cabinet through the plurality of monitoring units.

In the cabinet described above, through all-cabinet prefabrication, the connections between various parts within the cabinet are integrated. The entire cabinet only provides a PDU power supply interface and a CDU primary-side interface to the outside. During on-site installation, only the connection of the power supply interface, the connection of the CDU primary-side interface, and the connection between the liquid distribution unit and liquid cooling pipelines of various cold plate liquid cooling servers need to be completed, which greatly simplifies the wiring and pipeline connections work and reduces the on-site installation and configuration work.

In addition, in the cabinet provided by the embodiment of the present disclosure, the monitoring platform acquires state parameters of the cabinet through the plurality of monitoring units, and the state of the cabinet can be monitored by the monitoring platform. Meanwhile, the cooling medium of the liquid distribution unit and the air-liquid heat exchanger are both provided by the CDU. Through CDU, the flow rate and temperature of the cooling medium provided to the liquid distribution unit and the air-liquid heat exchanger can be adjusted easily to be suitable for application scenarios with different power densities.

In one possible embodiment, the air-liquid heat exchanger includes a heat dissipation coil.

In the cabinet described above, the air-liquid heat exchanger includes the heat dissipation coil only, and dissipates heat from the cabinet by means of a fan of the cold plate liquid cooling server without the need to setup a blower, which is suitable for scenarios with low power density and saves energy consumption.

In one possible embodiment, the air-liquid heat exchanger further includes at least one blower.

In the cabinet described above, the air-liquid heat exchanger may further include at least one blower, and dissipate heat from the cabinet by means of the fan of the cold plate liquid cooling server while assisting and accelerating the heat dissipation of the cabinet through the blower, which is suitable for scenarios with medium or large power density.

In one possible embodiment, the air-liquid heat exchanger is integrated in the rear-door frame of the cabinet.

In the cabinet described above, the air-liquid heat exchanger is integrated in the rear-door frame of the cabinet, that is, the back door including an air-liquid radiator is adopted instead of a conventional back door of the cabinet, without the need for arranging a separate cabinet to install an air-liquid radiator, thereby saving the occupied area of the machine room.

In one possible embodiment, a secondary-side liquid outlet of the CDU is connected with an inlet of the liquid distribution unit and an inlet of the air-liquid heat exchanger respectively through a first control valve; an outlet of the air-liquid heat exchanger is connected with the inlet of the liquid distribution unit and a secondary-side liquid return port of the CDU respectively through a second control valve; and an outlet of the liquid distribution unit is connected with the secondary-side liquid return port of the CDU.

In the cabinet described above, the secondary-side liquid outlet of the CDU is connected to the inlet of the liquid distribution unit and the inlet of the air-liquid heat exchanger respectively through the first control valve, and the outlet of the air-liquid heat exchanger is connected to the inlet of the liquid distribution unit and the secondary-side liquid return port of the CDU respectively through the second control valve. By controlling the first control valve and the second control valve, the heat dissipation mode of the cabinet can be flexibly switched to adjust the air-liquid ratio, thereby providing different refrigerating capacities.

In one possible implementation, the cabinet further includes: a controller, configured to control the first control valve and the second control valve to switch a heat dissipation mode of the cabinet.

In one possible embodiment, a joint heat dissipation mode includes a first heat dissipation mode, a second heat dissipation mode, and a third heat dissipation mode; where in the first heat dissipation mode, the secondary-side liquid outlet of the CDU is connected with the inlet of the air-liquid heat exchanger, the outlet of the air-liquid heat exchanger is connected with the inlet of the liquid distribution unit, and the outlet of the liquid distribution unit is connected with the secondary-side liquid return port of the CDU; in the second heat dissipation mode, the secondary-side liquid outlet of the CDU is connected with the inlet of the air-liquid heat exchanger and the inlet of the liquid distribution unit respectively, the outlet of the air-liquid heat exchanger is connected with the inlet of the liquid distribution unit, and the outlet of the liquid distribution unit is connected with the secondary-side liquid return port of the CDU; and in the third heat dissipation mode, the secondary-side liquid outlet of the CDU is connected with the inlet of the air-liquid heat exchanger and the inlet of the liquid distribution unit respectively, the outlet of the air-liquid heat exchanger and the outlet of the liquid distribution unit are both connected with the secondary-side liquid return port of the CDU.

For the cabinet described above, in the first heat dissipation mode, the air-liquid heat exchanger and the liquid distribution unit are connected in series, the cooling medium first passes through the air-liquid heat exchanger and then the liquid distribution unit. In the second heat dissipation mode, the air-liquid heat exchanger and the liquid distribution unit are connected in series, while the CDU provides the cooling medium to the liquid distribution unit. In the third heat dissipation mode, the air-liquid heat exchanger and the liquid distribution unit are connected in parallel, and the cooling medium passes through the air-liquid heat exchanger and the liquid distribution unit respectively. The three heat dissipation modes can provide different refrigerating capacities and can be flexibly switched based on the power consumption requirements of the cabinet to save energy consumption.

In one possible embodiment, the cabinet further includes: a touch display screen connected to the monitoring platform and configured to configure and/or display state parameters of the cabinet.

In one possible embodiment, the display screen is installed at a front door of the cabinet.

In the cabinet described above, the display screen is connected with the monitoring platform, and the state parameters of the cabinet can be displayed through the display screen, so that the operation and maintenance personnel can more intuitively understand the state of the cabinet.

In one possible embodiment, the cabinet further includes a liquid receiving tray arranged at a bottom of the cabinet, where the liquid receiving tray is provided with a water immersion sensor inside for detecting whether there is liquid accumulation in the liquid receiving tray.

In the cabinet described above, by arranging a liquid receiving tray at the bottom of the cabinet and a water immersion sensor for detecting whether there is liquid accumulation in the liquid receiving tray, it is possible to monitor whether the cabinet leaks liquid.

### BRIEF DESCRIPTION OF THE DRAWINGS

In order to more clearly illustrate the technical solutions in the embodiments of the present disclosure, the drawings to be used in the description of the embodiments are described briefly below. Apparently, the drawings in the following description show only some embodiments of the present disclosure, and those skilled in the art may obtain other drawings based on these drawings without any creative effort.

FIG. 1(a), FIG. 1(b) and FIG. 1(c) are a schematic structural diagram of a prefabricated air-liquid integrated cabinet provided by an embodiment of the present disclosure;

FIG. 2 is a schematic structural diagram of a rear-door back panel of a prefabricated air-liquid integrated cabinet provided by an embodiment of the present disclosure;

FIG. 3 is a schematic structural diagram of a front door of a prefabricated air-liquid integrated cabinet provided by an embodiment of the present disclosure;

FIG. 4 is a schematic diagram showing a connection relationship between a CDU, an air-liquid unit, and an air-liquid heat exchanger provided by an embodiment of the present disclosure;

FIG. 5 is a schematic diagram showing a principle of a first heat dissipation mode provided by an embodiment of the present disclosure;

FIG. 6 is a schematic diagram showing a principle of a second heat dissipation mode provided by an embodiment of the present disclosure;

FIG. 7 is a schematic diagram showing a principle of a third heat dissipation mode provided by an embodiment of the present disclosure;

FIG. 8 is a schematic structural diagram of another prefabricated air-liquid integrated cabinet provided by an embodiment of the present disclosure; and

FIG. 9 is a schematic structural diagram of still another prefabricated air-liquid integrated cabinet provided by an embodiment of the present disclosure.

### DETAILED DESCRIPTION

In order to make the objective, technical solution and advantages of the present disclosure clearer, the present disclosure will be further described in detail below in conjunction with the accompanying drawings. Apparently, the described embodiments are only some rather than all embodiments of the present disclosure. Based on the embodiments in the present disclosure, all other embodiments obtained by those skilled in the art without any creative work fall into the protection scope of the present disclosure.

In the description of the embodiments of the present disclosure, unless otherwise specified, "/" means or. For example, A/B may mean A or B; the "and/or" herein is only an association relationship that describes the associated objects, which means that there may be three kinds of relationships. For example, A and/or B may mean that there are three cases: A alone, A and B at the same time, and B alone. In addition, in the description of the embodiments of the present disclosure, "a plurality of" refers to two or more.

In the following, the terms "first", "second" and the like are used for the purpose of description only, and should not be interpreted as suggesting or implying relative importance or implicitly indicating the number of the indicated technical features. Therefore, features defined with "first", "second" and the like may explicitly or implicitly include one or more of such features.

Before introducing the prefabricated air-liquid integrated cabinet provided by the embodiment of the present disclosure, the technical background of the embodiment of the present disclosure is first introduced in detail to facilitate understanding.

A density of single cabinets continues to increase with the development of data centers. As a consequence, a conventional air-cooling mode can no longer fulfill heat dissipation requirements and the energy efficiency cannot fulfill relevant requirements. Future data centers will face multiple challenges of energy consumption and heat dissipation. Therefore, liquid cooling solutions have become the development trend for future data centers, and liquid cooling with cold plates is widely used as a relatively mature liquid cooling method.

In practical applications, liquid cooling and air cooling are often used in combination with each other. In a case that liquid cooling and air cooling are used in combination, shortcomings are as follows of 1 to 3.

1. On-site configuration is cumbersome, multiple pipeline channels need to be configured, and the power supply and distribution, wiring and pipeline connections work of pipeline systems are required to be completed on site.

2. The lack of an integrated monitoring platform and control platform makes it difficult to manage and intelligently control power supply and distribution, air-cooling and liquid-cooling data in one stop.

3. The air-liquid and liquid cooling systems are separated, and each requires an independent liquid cooling system, so that the on-site engineering layout is cumbersome. In addition, the control method of air-liquid ratio is single, the intelligence degree of the control is low, and the loss is large.

In view of this, a prefabricated air-liquid integrated cabinet is provided in the embodiment of the present disclosure, which integrates the connections between various parts within the cabinet through all-cabinet prefabrication. The entire cabinet only provides a PDU power supply interface and a CDU primary-side interface to the outside. During on-site installation, only the connection of the power supply interface, the connection of the CDU primary-side interface, and the connection between the liquid distribution unit and liquid cooling pipelines of various cold plate liquid cooling servers need to be completed, which greatly simplifies the wiring and pipeline connection work and reduces the on-site installation and configuration work.

In addition, in the cabinet provided by the embodiment of the present disclosure, the monitoring platform acquires state parameters of the cabinet through a plurality of monitoring units, and the state of the cabinet can be monitored by the monitoring platform. Meanwhile, the PDU can uniformly manage power supply and distribution for the cabinet, and the cooling medium of the liquid distribution unit and the air-liquid heat exchanger are both provided by the CDU. Through CDU, the flow rate and temperature of the cooling medium provided to the liquid distribution unit and the air-liquid heat exchanger can be easily adjusted to suit for application scenarios with different power densities.

After introducing the background technology of the embodiment of the present disclosure, the prefabricated air-liquid integrated cabinet provided by the embodiment of the present disclosure will be described in detail below in combination with specific embodiments.

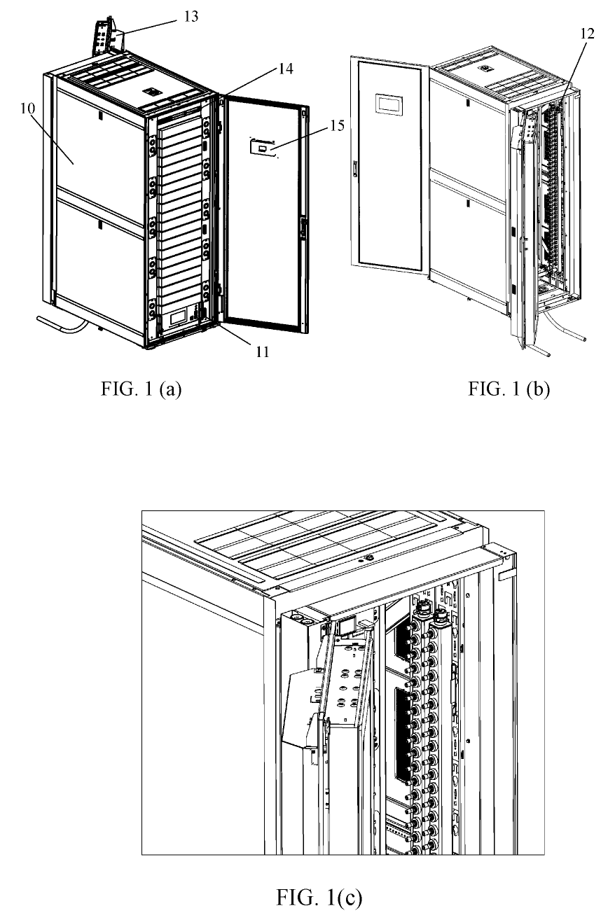

Reference is made to FIG. 1(a) and FIG. 1(b), which is a prefabricated air-liquid integrated cabinet according to an embodiment of the present disclosure. The prefabricated air-liquid integrated cabinet includes a PDU 10 integrated in the cabinet, a rack-based CDU 11, a liquid distribution unit 12, an air-liquid heat exchanger 13, a monitoring platform 14, and a plurality of monitoring units. FIG. 1(c) is an enlarged view of the liquid distribution unit 12 in FIG. 1(b).

The PDU 10 is connected with a power supply through a power supply interface provided by the cabinet to the outside, and is configured to supply power to at least the CDU 11, the air-liquid heat exchanger 13, the cold plate liquid cooling server installed in the cabinet, and the monitoring platform 14.

A primary side of the CDU 11 is connected to a cold source through heat exchange interface provided by the cabinet to the outside, and a secondary side of the CDU 11 is configured to provide a cooling medium to the liquid distribution unit 12 and the air-liquid heat exchanger 13.

It should be noted that the CDU may be arranged at the bottom of the cabinet and does not occupy space in the machine room. The primary side of the CDU refers to the side where the CDU exchanges heat with the outdoor cold source, and the secondary side of the CDU refers to the side where the CDU exchanges heat with the liquid distribution unit 12 and the air-liquid heat exchanger 13 in the cabinet. The cooling medium mentioned in the embodiment of the present disclosure may be deionized water, ethylene glycol, propylene glycol, or the like, which is not limited in the embodiment of the present disclosure.

The liquid distribution unit 12 is connected to the cold plate liquid cooling server, and is configured to supply the cooling medium provided by the CDU 11 to the cold plate liquid cooling server. In a case that a number of the cold plate liquid cooling server is more than one, the liquid distribution unit 12 allocates the cooling medium provided by the CDU 11 to each cold plate liquid cooling server, and the specific allocation method is not limited in the embodiment of the present disclosure.

The air-liquid heat exchanger 13 is configured to dissipate heat from the cabinet.

In specific implementations, the air-liquid heat exchanger 13 may be integrated in a rear-door frame of the cabinet. That is, a back door containing the air-liquid heat exchanger is adopted instead of the conventional back door of the cabinet to save the space in the machine room. The air-liquid heat exchanger 13 may include a heat dissipation coil only, and dissipate heat from the cabinet by means of a fan of the cold plate liquid cooling server without the need to set up a separate blower, which is suitable for scenarios with low power density and saves energy consumption. The air-liquid heat exchanger 13 may also include: the heat dissipation coil and at least one blower. In addition to dissipating heat from the cabinet by means of the fan of the cold plate liquid cooling server, the blower assists and accelerates the heat dissipation, so as to be suitable for scenarios with medium or large power density.

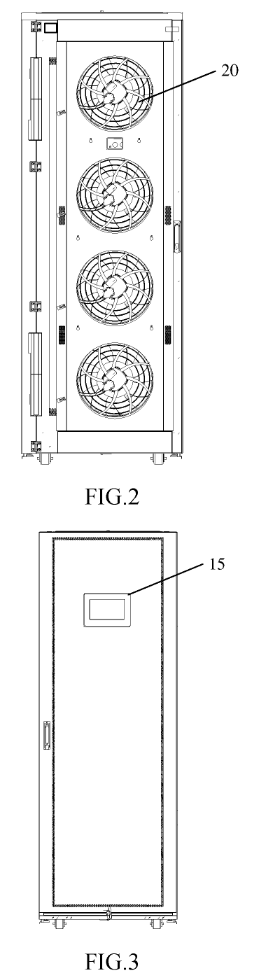

In one example, as shown in FIG. 2, the air-liquid heat exchanger installed on the rear-door back panel of the cabinet includes a heat dissipation coil and four blowers 20.

The monitoring platform 14 is configured to acquire state parameters of the cabinet through the plurality of monitoring units. The monitoring units are not shown in FIG. 1(a), FIG. 1(b) and FIG. 1(c), which may be various types of sensors or metering acquisition devices, such as temperature sensors, pressure sensors, flow sensors, door state sensors, flow meters, electronically controlled valves, or the like.

It should be noted that the state parameters of the cabinet include but are not limited to: a temperature in the cabinet, a pressure difference between inside and outside of the cabinet, information about PDU power supply and distribution, a temperature of the cooling medium provided by the CDU, a temperature of the cooling medium flowing back to the CDU, valve opening of the control valves (the first control valve and the second control valve mentioned in the embodiment of the present disclosure), a flow rate and temperature of the cooling medium in the pipeline, a rotation speed of the blower (the blower in the air-liquid heat exchanger 13), an air-supply temperature of the blower, a back-door temperature of the cabinet, or the like.

To display the state parameters of the cabinet more intuitively, the cabinet provided by the embodiment of the present disclosure further includes: a touch display screen 15 connected to the monitoring platform 14, and configured to configure and/or display the state parameters of the cabinet. Specifically, the touch display screen may employ a display screen with a Human Machine Interface (HMI).

As shown in FIG. 3, the touch display screen 15 may be installed on the front door of the cabinet. Specifically, the touch display screen 15 may be installed at any position of the front door, and FIG. 3 is for illustration only. In other embodiments of the present disclosure, the touch display screen 15 may also be installed at other locations of the cabinet.

In specific implementations, in order to monitor whether the cabinet leaks liquid, the cabinet further includes a liquid receiving tray arranged at the bottom of the cabinet, and the liquid receiving tray is provided with a water immersion sensor inside for detecting whether there is liquid accumulation in the liquid receiving tray. The water immersion sensor may trigger an alarm message when it detects that there is liquid accumulation in the liquid receiving tray. In other embodiments of the present disclosure, in a case that the alarm message is received, the monitoring platform 14 or a central control platform connected with the monitoring platform 14 may also jointly control the secondary side of the CDU to stop providing the cooling medium to the heat dissipation coil and/or the liquid distribution unit.

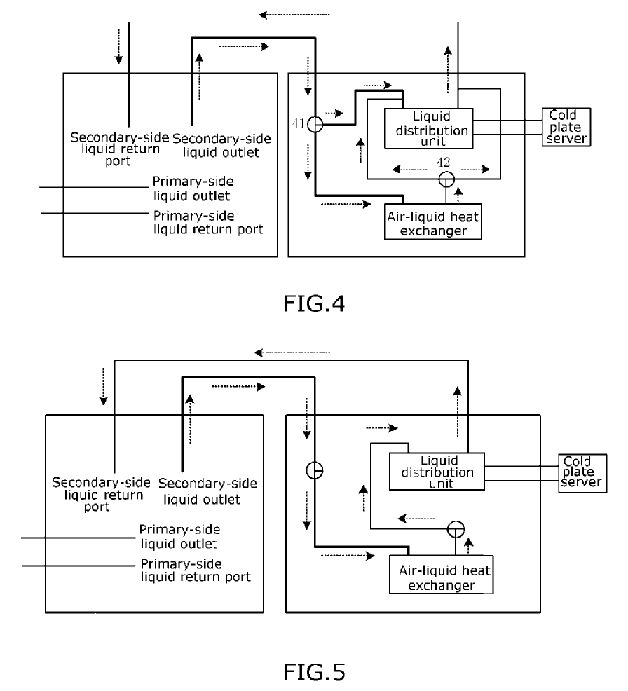

In the cabinet provided by the embodiment of the present disclosure, the cooling medium for the liquid distribution unit and the air-liquid heat exchanger are both provided by the CDU, and the specific connection structure thereof is as shown in FIG. 4. The secondary-side liquid outlet of the CDU is connected with an inlet of the liquid distribution unit and an inlet of the air-liquid heat exchanger respectively through a first control valve 41, an outlet of the air-liquid heat exchanger is connected with the inlet of liquid distribution unit and the secondary-side liquid return port of the CDU respectively through a second control valve 42, and the outlet of the liquid distribution unit is connected with the secondary-side liquid return port of the CDU. A solenoid valve or the like may be adopted as the first control valve and the second control valve, which is not limited in the embodiment of the present disclosure.

Specifically, the cabinet further includes a controller for controlling the first control valve and the second control valve and adjusting a heat dissipation mode of the cabinet under the control of a pre-configured control algorithm, thereby realizing optimal distribution of the cooling medium and reducing energy consumption.

The controller may be a single chip microcomputer, a processor, a digital signal processing chip, or the like. The controller may be integrated with the monitoring units, that is, the monitoring and control function is realized by the monitoring units. Alternatively, the controller may be arranged separately from the monitoring units, which is not limited in the embodiment of the present disclosure.

In specific implementations, the air-liquid heat exchanger and the liquid distribution unit share a set of cold source, and both are provided with the cooling medium by the CDU. In the connection pipelines of the CDU, the air-liquid heat exchanger and the liquid distribution unit, the first control valve and the second control valve are arranged, and several temperature sensors and several flow meters may also be arranged to obtain the temperature and flow rate of the cooling medium in the pipeline.

In practical applications, under the control of the pre-configured control algorithm, the controller, based on the temperature and flow rate of the cooling medium in the pipeline, may control the first control valve and the second control valve, and adjust the heat dissipation mode of the cabinet, that is, adjust the flow ratio (also called air-liquid ratio) of the air-liquid heat exchanger and the liquid distribution unit to be suitable for the actual power consumption requirements of the cabinet.

In practical applications, the heat dissipation mode includes a first heat dissipation mode, a second heat dissipation mode, and a third heat dissipation mode, and the above three heat dissipation modes are described below in combination with FIGS. 5-7, respectively.

As shown in FIG. 5, in the first heat dissipation mode, the secondary-side liquid outlet of the CDU is connected with the inlet of the air-liquid heat exchanger, the outlet of the air-liquid heat exchanger is connected with the inlet of the liquid distribution unit, and the outlet of the liquid distribution unit is connected with the secondary-side liquid return port of the CDU.

In this heat dissipation mode, the cooling medium first passes through the air-liquid heat exchanger and then the liquid distribution unit, and the cooling medium is recycled. This mode may be suitable for application scenarios with low power density.

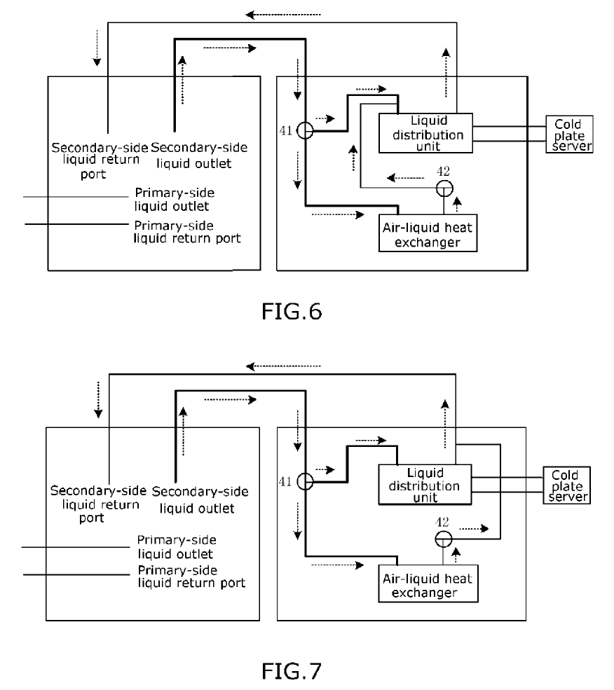

As shown in FIG. 6, in the second heat dissipation mode, the secondary-side liquid outlet of the CDU is connected with the inlet of the air-liquid heat exchanger and the inlet of the liquid distribution unit respectively, the outlet of the air-liquid heat exchanger is connected with the inlet of the liquid distribution unit, and the outlet of the liquid distribution unit is connected with the secondary-side liquid return port of the CDU.

In this heat dissipation mode, part of the cooling medium is directly provided to the liquid distribution unit by the CDU, and the other part of the cooling medium first passes through the air-liquid heat exchanger and then is provided to the liquid distribution unit, and the cooling medium is recycled. In this heat dissipation mode, hot and cold cooling medium may be mixed, heat exchange is circulated while cooling down. This mode may be suitable for scenarios with medium power density.

As shown in FIG. 7, in the third heat dissipation mode, the secondary-side liquid outlet of the CDU is connected with the inlet of the air-liquid heat exchanger and the inlet of the liquid distribution unit respectively, the outlet of the air-liquid heat exchanger and the outlet of the liquid distribution unit are both connected with the secondary-side liquid return port of the CDU.

In this heat dissipation mode, the cooling medium provided by the CDU is divided into two parts, one is supplied to the air-liquid radiator and the other is supplied to the liquid distribution unit. After the two parts undergo heat exchange respectively, the heat exchanged cooling medium converges and flows back to the CDU. This mode is suitable for scenarios with high power density.

In addition, the cabinet provided by the embodiment of the present disclosure may also integrate components such as a switch, which is not limited in the embodiment of the present disclosure.

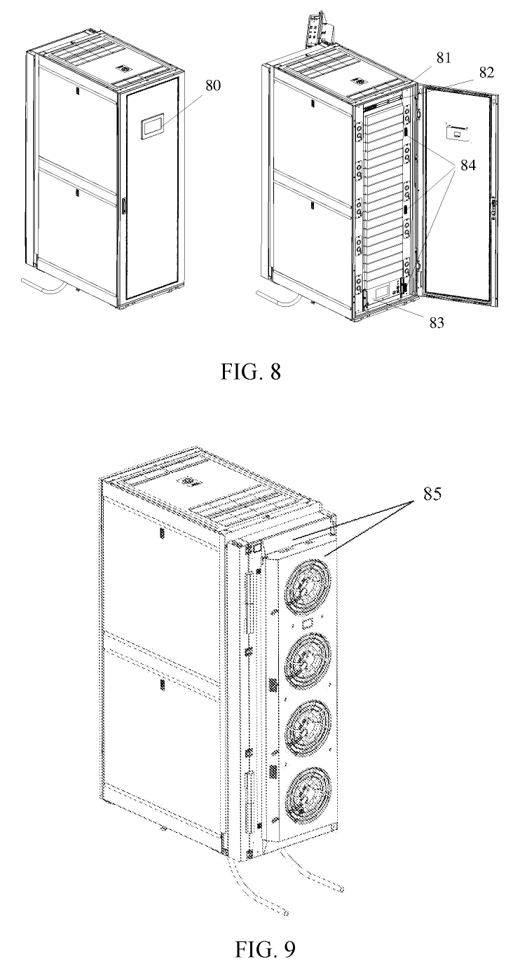

Hereinafter, the structure of the prefabricated air-liquid integrated cabinet provided by the embodiment of the present disclosure will be described as a whole in combination FIGS. 8 and 9.

As shown in FIG. 8, a display screen 80 is installed at the front door of the cabinet, and a switch 81, a monitoring platform 82, a rack-based CDU 83, and a plurality of front door temperature sensors 84 are integrated in the cabinet.

As shown in FIG. 9, the rear door of the cabinet adopts a backplane fan door 85 (that is, a backplane door installed with the air-liquid heat exchanger). The PDU, and a connection pipeline system of CDU with the air-liquid heat exchanger and the liquid distribution unit are integrated in the cabinet. There is a large area of heat dissipation coil on the backplane fan door. The heat generated at the rear end of the server is taken away by the cooling medium in the heat dissipation coil, and the cooled air are discharged to the indoor environment. In a case that the fan of the server is not enough to discharge the heat, the blower of the backplane fan door assists in heat dissipation and dissipates the heat accumulated at the back door of the cabinet.

The liquid receiving tray in which the water immersion sensor is installed is prefabricated at the bottom of the cabinet. Meanwhile, a door status sensor, a temperature sensor in a rear door of the cabinet, a cabinet pressure sensor, a blower supply-air temperature sensor and a bottom condensation sensor are prefabricated at the backplane fan door of the cabinet.

The prefabricated air-liquid integrated cabinet is provided by the embodiments of the present disclosure, and the cabinet is prefabricated with power supply system, liquid cooling system, the air-liquid heat exchanger and the pipeline system (the pipeline system formed by connections between the CDU and the liquid distribution unit, the air-liquid radiator), which can be prefabricated at one time and is highly integrated with core sub-components such as liquid cooling, power distribution and monitoring components, and has a high degree of prefabrication. During on-site installation and configuration, only the power supply for the PDU, the connection of the primary-side pipeline interface of the CDU and the liquid cooling pipeline connection between the liquid distribution unit and the cold plate liquid cooling server are required to be completed, all others are prefabricated, thereby highly reducing the on-site installation and configuration work.

Through the plurality of monitoring units and the monitoring platform, the state parameters of the cabinet such as the temperature in the cabinet, the pressure difference between inside and outside the cabinet, the power supply and distribution information of the PDU, the temperature of the liquid outlet of the CDU, the temperature of the liquid return port of the CDU, the valve opening of the solenoid valves (the first control valve and the second control valve), the flow rate of the pipeline, the temperature of the pipeline, the speed of the blower, the supply-air temperature of the blower, and the temperature of the back door of the cabinet may be monitored, and the state of the cabinet is modularly displayed on the HMI display screen. Through the pre-configured control algorithm, based on the state parameters of the cabinet, the flow rate and temperature of the cooling medium provided by the CDU are controlled, the opening of the solenoid valve is controlled, the solenoid valve is controlled to switch the heat dissipation mode, and the rotation speed of the blower is controlled, thereby achieving the optimal flow rate distribution of the air-liquid system and reducing energy consumption.

Apparently, those skilled in the art can make various variations and modifications to the present disclosure without departing from the spirit and the scope of the present disclosure. Thus, if these variations and modifications of the present disclosure fall within the scope of the claims of the present disclosure and equivalent technologies thereof, the present disclosure is intended to include these variations and modifications.

What is claimed is:

1. A prefabricated air-liquid integrated cabinet, characterized by comprising:
a power distribution unit, PDU, integrated in the cabinet,
an rack-based cooling distribution unit, CDU,
a liquid distribution unit,
an air-liquid heat exchanger,
a monitoring platform, and
a plurality of monitoring units,
wherein the PDU is connected with a power supply through a power supply interface provided by the cabinet to the outside, and is configured to supply power to at least the CDU, the air-liquid heat exchanger, a cold plate liquid cooling server installed in the cabinet, and the monitoring platform;
a primary side of the CDU is connected with a cold source through a heat exchange interface provided by the cabinet to the outside, and a secondary side of the CDU is configured to provide a cooling medium to the liquid distribution unit and the air-liquid heat exchanger;
the liquid distribution unit is connected to the cold plate liquid cooling server installed in the cabinet, and is configured to supply the cooling medium provided by the CDU to the cold plate liquid cooling server;
the air-liquid heat exchanger is configured to dissipate heat from the cabinet; and
the monitoring platform is configured to acquire state parameters of the cabinet through the plurality of monitoring units.

2. The cabinet according to claim 1, characterized in that the air-liquid heat exchanger comprises a heat dissipation coil.

3. The cabinet according to claim 2, characterized in that the air-liquid heat exchanger further comprises at least one blower.

4. The cabinet according to claim 1, characterized in that the air-liquid heat exchanger is integrated in a rear-door frame of the cabinet.

5. The cabinet according to claim 1, characterized in that
a secondary-side liquid outlet of the CDU is connected with an inlet of the liquid distribution unit and an inlet of the air-liquid heat exchanger respectively through a first control valve;
an outlet of the air-liquid heat exchanger is connected with the inlet of the liquid distribution unit and a secondary-side liquid return port of the CDU respectively through a second control valve; and
an outlet of the liquid distribution unit is connected with the secondary-side liquid return port of the CDU.

6. The cabinet according to claim 5, characterized in that the cabinet further comprises:
a controller configured to control the first control valve and the second control valve, and to switch a heat dissipation mode of the cabinet.

7. The cabinet according to claim 6, characterized in that the heat dissipation mode includes a first heat dissipation mode, a second heat dissipation mode, and a third heat dissipation mode;
in the first heat dissipation mode, the secondary-side liquid outlet of the CDU is connected with the inlet of the air-liquid heat exchanger, the outlet of the air-liquid heat exchanger is connected with the inlet of the liquid distribution unit, and the outlet of the liquid distribution unit is connected with the secondary-side liquid return port of the CDU;
in the second heat dissipation mode, the secondary-side liquid outlet of the CDU is connected with the inlet of the air-liquid heat exchanger and the inlet of the liquid distribution unit respectively, the outlet of the air-liquid heat exchanger is connected with the inlet of the liquid distribution unit, and the outlet of the liquid distribution unit is connected with the secondary-side liquid return port of the CDU; and
in the third heat dissipation mode, the secondary-side liquid outlet of the CDU is connected with the inlet of the air-liquid heat exchanger and the inlet of the liquid distribution unit respectively, the outlet of the air-liquid heat exchanger and the outlet of the liquid distribution unit are both connected with the secondary-side liquid return port of the CDU.

8. The cabinet according to claim 1, characterized in that the cabinet further comprises: a touch display screen connected to the monitoring platform and configured to configure and/or display state parameters of the cabinet.

9. The cabinet according to claim 8, characterized in that the touch display screen is installed at a front door of the cabinet.

10. The cabinet according to claim 1, characterized in that the cabinet further comprises a liquid receiving tray arranged at a bottom of the cabinet, wherein the liquid receiving tray is provided with a water immersion sensor inside for detecting whether there is liquid accumulation in the liquid receiving tray.
